(19) United States
(12) Patent Application Publication
(10) Pub. No.: US 2024/0196706 A1
(43) Pub. Date: Jun. 13, 2024

(54) FLEXIBLE COVER WINDOW ASSEMBLY AND FLEXIBLE DISPLAY DEVICE INCLUDING THE SAME

(71) Applicant: LG Display Co., Ltd., Seoul (KR)

(72) Inventors: Sungsik SON, Gumi-si (KR); Wooseok CHO, Gumi-si (KR)

(73) Assignee: LG Display Co., Ltd., Seoul (KR)

(21) Appl. No.: 18/531,127

(22) Filed: Dec. 6, 2023

(30) Foreign Application Priority Data
Dec. 7, 2022 (KR) 10-2022-0169520

(51) Int. Cl. H10K 59/80

(52) U.S. Cl. CPC H10K 59/873; H10K 59/8794; H10K 59/8791; H10K 2102/311

(57) ABSTRACT

A flexible display device includes a flexible cover window having a base film, a light-blocking layer disposed on and along an edge of a lower surface of the base film of the flexible cover window, a display module disposed under the flexible cover window, a support plate disposed under the display module, and a heat-dissipating plate disposed under the support plate. The flexible cover window further includes an anti-glare layer, an anti-reflection layer and an anti-fingerprint layer sequentially stacked on an upper surface of the base film.

### CROSS-REFERENCE TO RELATED APPLICATION

This application claims priority to Korean Patent Application No. 10-2022-0169520 filed on Dec. 7, 2022 in the Korean Intellectual Property Office, the entire contents of which are hereby expressly incorporated by reference into the present application.

### BACKGROUND

### Field

The present disclosure relates to a flexible cover window assembly and a flexible display device including the same.

### Discussion of Related Art

A liquid crystal display (LCD) device, an organic light-emitting diode display device, an inorganic light-emitting diode display device, and a quantum dot (QD) display device as a flat panel display device have been studied and developed.

Further, various types of flexible display devices such as a foldable or bendable display device in which a display panel can be bended or folded, and a slidable or rollable display device in which the display panel can be rolled on a roller has been developed.

The flexible display device may be used in a wide variety of information devices such as televisions, monitors, smartphones, tablet PCs, notebooks, and wearable devices. On the other hand, various vehicle display devices such as a digital dashboard (or cluster), a central information display (CID), and a rear seat entertainment (RSE) display are used. In order to integrate technologies directed to these devices, attempts are being made to apply the flexible display device to these vehicle display devices.

### SUMMARY OF THE DISCLOSURE

A flexible display device needs a flexible cover window to protect a display panel.

The flexible cover window used in a slidable or rollable display device has a structure in which an anti-scattering film having various functional layers (for example, an anti-glare layer, an anti-reflection layer, and an anti-fingerprint layer) coated thereon is attached onto a top surface of a thin cover glass. Further, a black ink layer is coated on an edge of a lower surface of the cover glass.

However, the flexible cover window having the above-described structure may not be used in a foldable or bendable display device, since such device is folded at a smaller radius of curvature than that at which the slidable or rollable display device is bent, due to cracks in the cover glass.

Therefore, the inventors of the present disclosure have developed a new flexible cover window assembly applicable not only to various slidable or rollable display devices but also to various foldable or bendable display devices, and a flexible display device including the same.

A technical purpose according to embodiments of the present disclosure is to provide a flexible cover window assembly applicable not only to the slidable or rollable display devices but also to the foldable or bendable display devices, and a flexible display device including the same.

Purposes according to the present disclosure are not limited to the above-mentioned purpose. Other purposes and advantages according to the present disclosure that are not mentioned can be understood based on following descriptions, and can be more clearly understood based on embodiments according to the present disclosure. Further, it will be easily understood that the purposes and advantages according to the present disclosure can be realized using means shown in the claims or combinations thereof.

One aspect of the present disclosure provides a flexible display device comprising: a flexible cover window including a base film, and an anti-glare layer, an anti-reflection layer and an anti-fingerprint layer sequentially stacked on an upper surface of the base film; a light-blocking layer disposed on and along an edge of a lower surface of the base film of the flexible cover window; a display module disposed under the flexible cover window; a support plate disposed under the display module; and a heat-dissipating plate disposed under the support plate.

Another aspect of the present disclosure provides a flexible cover window assembly comprising: a flexible cover window including a base film, an anti-glare layer, an anti-reflection layer and an anti-fingerprint layer, where the anti-glare layer, the anti-reflection layer and the anti-fingerprint layer are sequentially stacked on an upper surface of the base film; a light-blocking layer disposed along and on an edge of a lower surface of the base film of the flexible cover window; and an adhesive layer disposed on a lower surface of the flexible cover window.

Details of the other embodiments are included in the detailed descriptions and drawings.

According to the aspects of the present disclosure, the flexible cover window assembly does not include a thin cover glass. Thus, a manufacturing process thereof can be simple and a material cost thereof can be reduced, compared to a conventional flexible cover window assembly including a thin cover glass.

Further, according to the aspects of the present disclosure, the flexible cover window assembly does not include a thin cover glass, and thus can be cut in a laser trimming manner, and thus can have a smoother outer line compared to a related art flexible cover window assembly having a thin cover glass.

Further, according to the aspects of the present disclosure, the upper wing, the left wing, and the right wing of the flexible cover window respectively surround the side surfaces of the display module. Thus, the side surfaces of the display module can be prevented from being exposed to the outside.

Further, according to the aspects of the present disclosure, the foam pads are respectively disposed between the upper wing, the left wing and the right wing of the flexible cover window and the side surfaces of the display module. Thus, the display module can be protected from external impact.

Further, according to the aspects of the present disclosure, each of the through-holes of the heat-dissipating plate has a bent structure in the heat-dissipating plate. Thus, a defect or other issue in which the heat-dissipating plate is peeled off can be prevented due to the increase in an adhesive area between the adhesive layer and the heat-dissipating plate.

Effects of the present disclosure are not limited to the effects mentioned above, and other effects not mentioned will be clearly understood by those skilled in the art from the descriptions below.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is a plan view showing a display device according to one embodiment of the present disclosure.

FIG. 2 is an exploded perspective view showing a display device according to one embodiment of the present disclosure.

FIG. 3 is a development view of a flexible cover window according to one embodiment of the present disclosure.

FIG. 4 is a cross-sectional view taken along line 4-4 in FIG. 1.

FIG. 5 is a cross-sectional view taken along line 5-5 in FIG. 1.

FIG. 6 shows a heat-dissipating plate according to one embodiment of the present disclosure.

### DETAILED DESCRIPTION OF THE EMBODIMENTS

Advantages and features of the present disclosure, and a method of achieving the advantages and features will become apparent with reference to embodiments described later in detail together with the accompanying drawings. However, the present disclosure is not limited to the embodiments as disclosed under, but can be implemented in various different forms. Thus, these embodiments are set forth only to make the present disclosure complete, and to completely inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure can be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as can be included in the spirit and scope of the present disclosure as defined by the appended claims.

A shape, a size, a ratio, an angle, a number, etc., disclosed in the drawings for describing embodiments of the present disclosure are illustrative, and the present disclosure is not limited thereto. The same reference numerals refer to the same elements herein. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure can be practiced without these specific details. In other instances, well-known methods, procedures, components, and circuits have not been described in detail so as not to unnecessarily obscure aspects of the present disclosure.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements can modify the entire list of elements and may not modify the individual elements of the list. In interpretation of numerical values, an error or tolerance therein can occur even when there is no explicit description thereof.

In addition, it will also be understood that when a first element or layer is referred to as being present “on” a second element or layer, the first element can be disposed directly on the second element or can be disposed indirectly on the second element with one or more additional elements or layers being disposed between the first and second elements or layers. It will be understood that when an element or layer is referred to as being “connected to”, or “connected to” another element or layer, it can be directly on, connected to, or connected to the other element or layer, or one or more intervening elements or layers can be present. In addition, it will also be understood that when an element or layer is referred to as being “between” two elements or layers, it can be the only element or layer between the two elements or layers, or one or more intervening elements or layers can also be present.

Further, as used herein, when a layer, film, region, plate, or the like is disposed “on” or “on a top” of another layer, film, region, plate, or the like, the former can directly contact the latter or still one or more other layers, films, regions, plates, or the like can be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former can directly contact the latter or still one or more layers, films, regions, plates, or the like can be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event can occur therebetween unless “directly after”, “directly subsequent” or “directly before” is indicated.

When a certain embodiment can be implemented differently, a function or an operation specified in a specific block can occur in a different order from an order specified in a flowchart. For example, two blocks in succession can be actually performed substantially concurrently, or the two blocks can be performed in a reverse order depending on a function or operation involved.

It will be understood that, although the terms “first”, “second”, “third”, and so on can be used herein to describe various elements, components, regions, layers and/or sections, these elements, components, regions, layers and/or sections should not be limited by these terms. These terms are used to distinguish one element, component, region, layer or section from another element, component, region, layer or section, and may not define order or sequence. Thus, a first element, component, region, layer or section described under could be termed a second element, component, region, layer or section, without departing from the spirit and scope of the present disclosure.

The features of the various embodiments of the present disclosure can be partially or entirely combined with each other, and can be technically associated with each other or operate with each other. The embodiments can be implemented independently of each other and can be implemented together in an association relationship.

In interpreting a numerical value, the value is interpreted as including an error range unless there is separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, and the like should not be construed such that any aspect or design as described is superior to or advantageous over other aspects or designs.

Further, the term ‘or’ means ‘inclusive or’ rather than ‘exclusive or’. That is, unless otherwise stated or clear from the context, the expression that ‘x uses a or b’ means any one of natural inclusive permutations.

The terms used in the description below have been selected as being general and universal in the related technical field. However, there can be other terms than the terms depending on the development and/or change of technology, convention, preference of technicians, etc. Therefore, the terms used in the description below should not be understood as limiting technical ideas, but should be understood as examples of the terms for describing embodiments.

Further, in a specific case, a term can be arbitrarily selected by the applicant, and in this case, the detailed meaning thereof will be described in a corresponding description section. Therefore, the terms used in the description below should be understood based on not simply the name of the terms, but the meaning of the terms and the contents throughout the Detailed Descriptions.

Hereinafter, a display device according to embodiments of the present disclosure will be described in detail with reference to the accompanying drawings. All the components of each display device or apparatus according to all embodiments of the present disclosure are operatively coupled and configured.

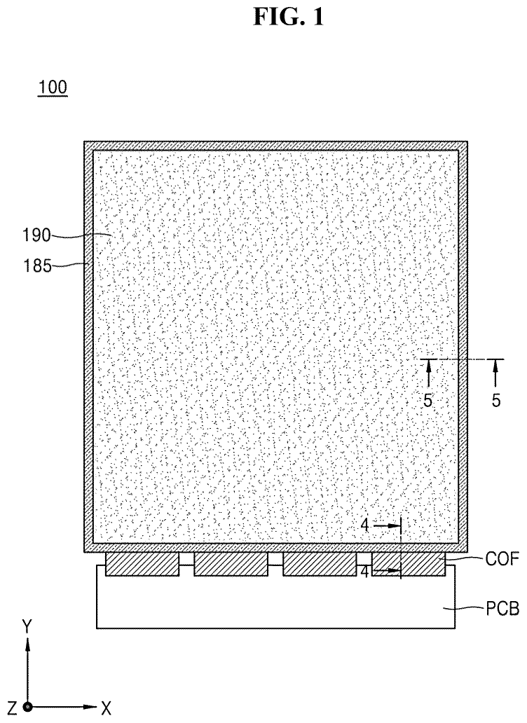

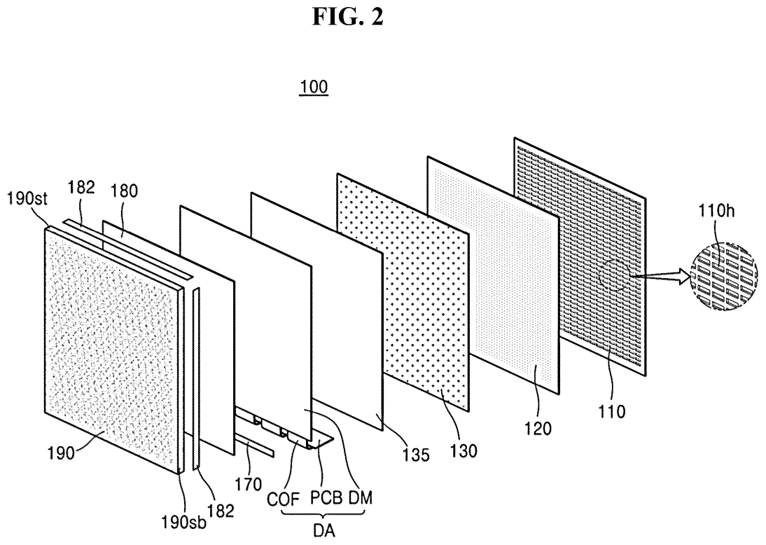

FIG. 1 is a plan view showing a display device according to one embodiment of the present disclosure. FIG. 2 is an exploded perspective view showing a display device according to one embodiment of the present disclosure.

Referring to FIG. 1 and FIG. 2, a display device 100 according to the embodiment of the present disclosure can include a flexible cover window 190, a foam pad 182, a filling film 170, a display module assembly DA, a support plate 130, and a heat-dissipating plate 110. The display module assembly DA can include a display module DM, a chip-on-film COF and a printed circuit board PCB. A light-blocking layer 185 can be disposed on a lower surface of the flexible cover window 190.

The flexible cover window 190 can be made of a transparent material so that light emitted from the display module DM can pass therethrough. The flexible cover window 190 can protect components of the display module DM, especially, a display panel from external impact, moisture, and heat.

The support plate 130 supports the display module DM, and the heat-dissipating plate 110 can dissipate heat generated from the display module DM to the outside while supporting the display module DM. The heat-dissipating plate 110 can have a plurality of through-holes 110h defined therein, and thus can have flexibility.

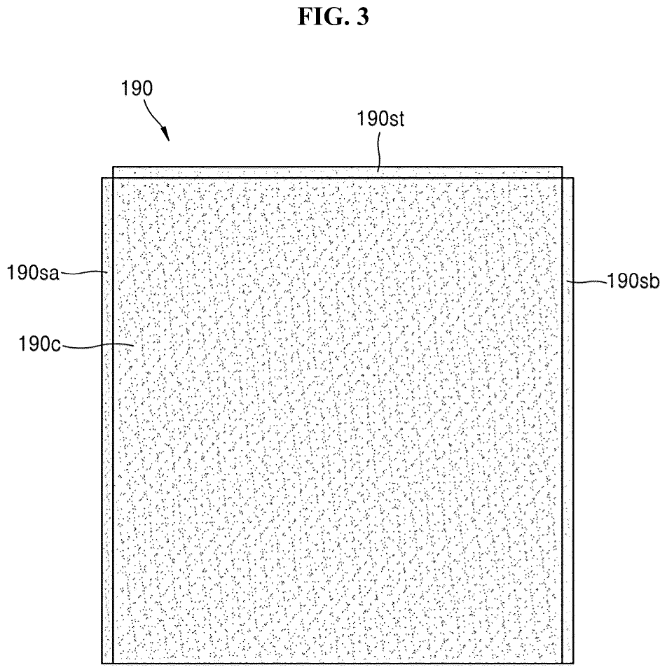

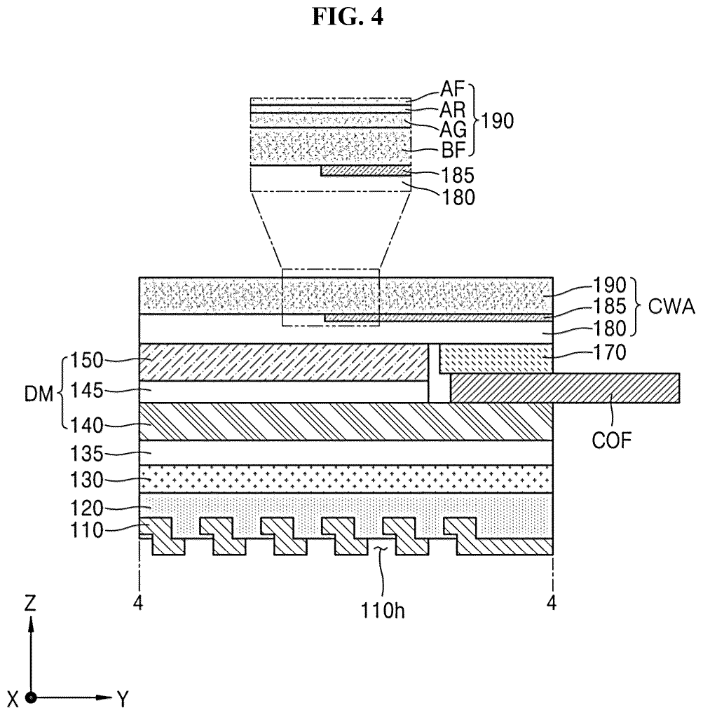

The printed circuit board PCB can be connected to the display module DM via the chip-on-film COF. A driver chip for driving the display panel of the display module DM can be mounted on the chip-on-film COF and the printed circuit board PCB. Some of the elements shown in FIG. 2 will be discussed later in more detail referring to FIGS. 3 and 4.

FIG. 3 is a development view of a flexible cover window according to one embodiment of the present disclosure.

Referring to FIG. 3, the flexible cover window 190 can include a flat portion 190c, an upper wing 190st, a left wing 190sa, and a right wing 190sb. The upper wing 190st can extend from an upper side of the flat portion 190c, the left wing 190sa can extend from a left side of the flat portion 190c, and the right wing 190sb can extend from a right side of the flat portion 190c. Here, the terms such as right, left, top, bottom, etc. are not fixed terms and are used to describe relational positions. For example, left can be right and right can be left, depending on the view perspective.

After the flat portion 190c of the flexible cover window 190 is attached to the display module DM, the upper wing 190st, the left wing 190sa, and the right wing 190sb of the flexible cover window 190 can be bent so as to cover side surfaces of the display module DM, respectively. FIG. 4 is a cross-sectional view taken along line 4-4 in FIG. 1.

Referring to FIG. 4, the flexible cover window 190 can include a base film BF, an anti-glare layer AG disposed on the base film BF, an anti-reflection layer AR disposed on the anti-glare layer AG, and an anti-fingerprint layer AF disposed as a top layer and on the anti-reflection layer AR.

The base film BF can be a transparent film, for example, a film having excellent transparency having visible light transmittance of 85% or greater. The base film BF can be made of, for example, polyolefin such as polyethylene (PE) and polypropylene (PP), polyester such as polyethylene terephthalate (PET) and polyethylene naphthalate, cellulose such as triacetyl cellulose (TAC), diacetyl cellulose, propionyl cellulose, butyl cellulose and acetyl cellulose, a polymer material such as polyamide, polystyrene, polyvinyl chloride (PVC), polyimide (PI), polyvinylalcohol (PVA), polycarbonate (PC), or ethylene vinyl alcohol (EVOH), etc. However, the present disclosure is not limited thereto. A thickness of the base film BF can be in a range of 80 μm to 150 μm.

The anti-glare layer AG can reduce reflectance of external light to increase visibility. For example, the anti-glare layer AG can have a concave-convex structure on a top surface thereof to scatter light to reduce reflectance and prevent glare. A thickness of the anti-glare layer AG can be in a range of 3 μm to 10 μm.

The anti-reflection layer AR can have a structure that low refractive index material layers and high refractive index material layers are alternately coated with each other on a surface thereof to provide an effect of reducing reflectance based on destructive interference in an interfacial reflection process. A thickness of the anti-reflection layer AR can be in a range of 0.1 μm to 1 μm.

The anti-fingerprint layer AF can have a special treated surface to allow fingerprints and other stains not to remain thereon. The anti-fingerprint layer AF uses a water-repellent or oil-repellent function to prevent contaminants from remaining thereon, so that the fingerprints can be less stained thereon or easily erased therefrom. A thickness of the anti-fingerprint layer AF can be in a range of 0.1 μm to 1 μm.

The light-blocking layer 185 can be disposed on a lower surface of the flexible cover window 190. The light-blocking layer 185 can be disposed directly on the lower surface of the base film BF of the flexible cover window 190. The light-blocking layer 185 can be disposed on an edge area of the flexible cover window 190. The light-blocking layer 185 can overlap a non-display area of the display module DM such that various lines disposed in the non-display area of the display module DM can be prevented from being visually recognized by a viewer.

The light-blocking layer 185 can be disposed not only on the edge area of the lower surface of the flat portion 190c of the flexible cover window 190, but also on a lower surface of each of the upper wing 190st, the left wing 190sa, and the right wing 190sb of the flexible cover window 190. The light-blocking layer 185 can be formed by, for example, coating black ink and then curing the same.

An adhesive layer 180 can be disposed on the lower surface of the flexible cover window 190. Thus, the flexible cover window 190 can be attached to the display module DM via the adhesive layer 180. The adhesive layer 180 can overlap at least a portion of the light-blocking layer 185 formed on the lower surface of the flexible cover window 190. The adhesive layer 180 can be an adhesive member including OCA (Optical Clear Adhesive), OCR (Optical Clear Resin), and the like.

The flexible cover window 190, the light-blocking layer 185 and the adhesive layer 180 can collectively constitute a cover window assembly CWA.

Since the flexible cover window assembly CWA according to this embodiment does not include a thin cover glass, a manufacturing process thereof can be simple and a material cost thereof can be reduced, compared to a conventional flexible cover window assembly including the thin cover glass.

Further, the flexible cover window assembly CWA according to this embodiment does not include a thin cover glass, and thus can be cut in a laser trimming manner, and thus can have a smoother outer line compared to a conventional flexible cover window assembly having the thin cover glass.

The display module DM can include a display panel 140, a polarizer 150, and an adhesive layer 145 disposed therebetween.

The display panel 140 can be a flexible display panel. For example, the display panel 140 can be an organic light-emitting diode display panel formed on a flexible substrate. However, the present disclosure is not limited thereto. The display panel 140 can be of various types, such as a liquid crystal display panel, an inorganic light-emitting diode display panel, and a quantum dot display panel.

When the display panel 140 is embodied as the organic light-emitting diode display panel, the display panel 140 can include a thin-film transistor array in which thin-film transistors (including switching thin-film transistors and driving thin-film transistors) are formed on the flexible substrate and in each pixel, an organic light-emitting element disposed in each pixel and connected to the driving thin-film transistor, and an encapsulation layer covering the organic light-emitting elements so as to prevent moisture and oxygen from the outside from invading the organic light-emitting elements.

The polarizer 150 can be disposed on the display panel 140 to prevent reflection of light introduced from the outside to provide a function of improving visibility of the display panel 140. The polarizer 150 can include a polarizer and a phase retardation layer. The adhesive layer 145 can be an adhesive member including an optical clear adhesive (OCA) or an optical clear resin (OCR), and the like.

In one embodiment, the display module DM can further include a touch panel disposed on the polarizer 150 and an adhesive layer attaching the touch panel to the polarizer 150. The touch panel can be disposed between the flexible cover window 190 and the polarizer 150 to provide a touch function that detects a touch input such as a stylus pen or a user's finger. The touch panel can be attached to the flexible cover window 190 via an adhesive layer 180. In one embodiment, instead of disposing the touch panel on the polarizer 150, a touch electrode necessary for touch recognition can be disposed on the encapsulation layer of the display panel 140.

A light control film can be further disposed on the display module DM. The light control film can adjust a propagation angle of light emitted from the display panel 140 relative to a vertical direction or a left and right direction to prevent a viewing angle from being increased in an unnecessary direction. The light control film can be attached onto the display module DM by an adhesive member including an optical clear adhesive (OCA) or the like.

The support plate 130 can be attached to a lower surface of the display panel 140 via an adhesive layer 135 to support the display panel 140 thereon. The support plate 130 can be made of, for example, a polymer material or a metal material. The polymer material can include, for example, polymethylmethacrylate (PMMA), polycarbonate (PC), polyacrylate (PA), polyvinylalcohol (PVA), acrylonitrile-butadiene-styrene (ABS), polyethylene terephthalate (PET), or polyimide (PI). However, the present disclosure is not limited thereto. The adhesive layer 135 can be an adhesive member including an optical clear adhesive (OCA) or the like.

To drive the display panel 140, the chip-on-film COF can be attached to a pad area of the display panel 140. The polarizer 150 can be attached to a display area of the display panel 140. When the flexible cover window 190 having the light-blocking layer 185 formed thereon is attached onto the polarizer 150 via the adhesive layer 180, a space is formed between the flexible cover window 190 and the chip-on-film COF. Specifically, the space is defined between the adhesive layer 180 attached to the lower surface of the flexible cover window 190 and the chip-on-film COF. A filling film 170 can fill this space.

The filling film 170 can be attached to the adhesive layer 180. An adhesive member may not be disposed between the filling film 170 and the chip-on-film COF. When the filling film 170 fills the space between the flexible cover window 190 and the chip-on-film COF, the flexible cover window 190 in a form of a thin film can be prevented from sagging such that a flatness of the flexible cover window 190 can be maintained.

The filling film 170 can be made of, for example, polyolefin such as polyethylene (PE) and polypropylene (PP), polyester such as polyethylene terephthalate (PET) and polyethylene naphthalate, cellulose such as triacetyl cellulose (TAC), diacetyl cellulose, propionyl cellulose, butyl cellulose and acetyl cellulose, a polymer material such as polyamide, polystyrene, polyvinyl chloride (PVC), polyimide (PI), polyvinylalcohol (PVA), polycarbonate (PC), or ethylene vinyl alcohol (EVOH), etc. However, the present disclosure is not limited thereto.

When the display panel 140 is embodied as an organic light-emitting diode display panel, organic light-emitting elements thereof can be deteriorated due to heat generated during operation thereof. Thus, it is important to dissipate the heat to the outside.

The heat-dissipating plate 110 can be attached to the support plate 130 via an adhesive layer 120 and can dissipate the heat generated from the display panel 140 to the outside. Further, the heat-dissipating plate 110 can have a plurality of through-holes 110h defined therein so that the display device 100 can be foldable or rollable around a roller.

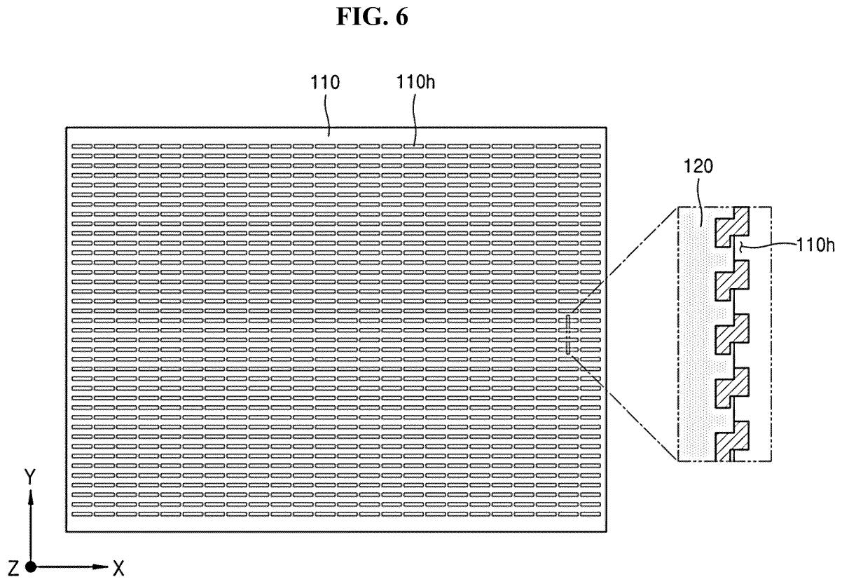

FIG. 6 shows a heat-dissipating plate according to one embodiment of the present disclosure.

Referring to FIG. 4 and FIG. 6 together, each of the plurality of through-holes 110h can have a dimension in a first direction (e.g., X-axis direction) and a dimension in a second direction (e.g., Y-axis direction) different from each other.

Referring to FIG. 6, the dimension in the first direction (e.g., X-axis direction) is larger than the dimension in the second direction (e.g., Y-axis direction). In this case, the heat-dissipating plate 110 can be folded or rolled in the Y-axis direction. The plurality of through-holes 110h can be arranged so as to be spaced apart from each other in the first direction (X-axis direction) and the second direction (Y-axis direction). The shape and the arrangement of the plurality of through-holes 110h are not limited to those shown in FIG. 6.

Each through-hole 110h can have a bent structure in the heat-dissipating plate 110. Accordingly, a sidewall and a protrusion extending from the sidewall can be formed in the through-hole 110h of the heat-dissipating plate 110 contacting the adhesive layer 120. When the adhesive layer 120 and the heat-dissipating plate 110 are attached to each other, at least a portion of the protrusion formed in the through-hole 110h of the heat-dissipating plate 110 can be positioned in the adhesive layer 120. An entirety of the protrusion formed in the through-hole 110h is disposed in the adhesive layer 120 so that the adhesive layer 120 can entirely cover the protrusion formed in the through-hole 110h. As a result, an adhesive area between the adhesive layer 120 and the heat-dissipating plate 110 can be increased, thereby preventing a peeling defect between the adhesive layer 120 and the heat-dissipating plate 110.

When the display device 100 is embodied as a rollable display device, the plurality of through-holes 110h of the heat-dissipating plate 110 can be formed over an entire area of the display device 100. When the display device 100 is embodied as a foldable or bendable display device, the plurality of through-holes 110h of the heat-dissipating plate 110 can be formed locally only in a bendable area of the display device 100.

The heat-dissipating plate 110 can be made of metal, for example, gold, silver, magnesium, aluminum or copper. The adhesive layer 120 can be an adhesive member including OCA (Optical Clear Adhesive), OCR (Optical Clear Resin), and the like, and can further contain thermally conductive materials.

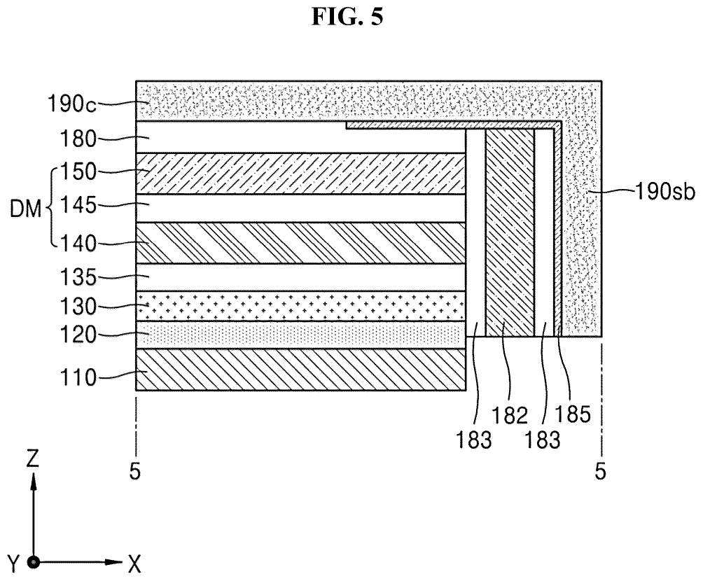

FIG. 5 is a cross-sectional view taken along line 5-5 in FIG. 1.

Referring to FIG. 5, the right wing 190sb of the flexible cover window 190 is bent from the flat portion 190c of the cover window 190 so as to cover at least a right side surface of the display module DM. The foam pad 182 can be disposed between the right wing 190sb of the flexible cover window 190 and a right side surface of the display module DM. The foam pad 182 can be attached to the display module DM, and the light-blocking layer 185 disposed on the lower surface of the flexible cover window 190 via an adhesive layer 183.

The upper wing 190st and the left wing 190sa of the flexible cover window 190 can be bent from the flat portion 190c of the flexible cover window 190 so as to cover at least upper and left side surfaces of the display module DM, respectively. Further, the foam pad 182 and the adhesive layer 183 can be disposed between the upper wing 190st of the flexible cover window 190 and the upper side surface of the display module DM, and between the left wing 190sa of the flexible cover window 190 and the left side surface of the display module DM.

The upper wing 190st, the left wing 190sa and the right wing 190sb of the flexible cover window 190 can cover a side surface of the support plate 130 disposed under the display module DM. In one embodiment, the upper wing 190st, the left wing 190sa, and the right wing 190sb of the flexible cover window 190 can cover a side surface of the heat-dissipating plate 110 disposed under the display module DM. In this case, a dimension of each of the foam pad 182 and the adhesive layer 183 can be increased based on a dimension of each of the upper wing 190st, the left wing 190sa, and the right wing 190sb of the flexible cover window 190.

In this embodiment, the upper wing 190st, the left wing 190sa, and the right wing 190sb of the flexible cover window 190 surround the side surfaces of the display module DM. Thus, the side surfaces of the display module DM can be prevented from being exposed to the outside. Further, the foam pad 182 can be disposed between the upper wing 190st, the left wing 190sa and the right wing 190sb of the flexible cover window 190 and the side surfaces of the display module DM, respectively, such that the display module DM can be protected from external impact.

A flexible display device and a flexible cover window assembly according to embodiments of the present disclosure can be described as follows.

A first aspect of the present disclosure provides a flexible display device comprising: a flexible cover window including a base film, and an anti-glare layer, an anti-reflection layer and an anti-fingerprint layer sequentially stacked on an upper surface of the base film; a light-blocking layer disposed on and along an edge of a lower surface of the base film of the flexible cover window; a display module disposed under the flexible cover window; a support plate disposed under the display module; and a heat-dissipating plate disposed under the support plate.

In some implementations of the flexible display device, the flexible cover window includes a flat portion, an upper wing extending from an upper side of the flat portion, a left wing extending from a left side of the flat portion, and a right wing extending from a right side of the flat portion.

In some implementations of the flexible display device, the upper wing, the left wing and the right wing of the flexible cover window respectively cover upper, left and right side surfaces of the display module.

In some implementations of the flexible display device, the light-blocking layer is disposed not only on the edge of the lower surface of the flat portion of the flexible cover window but also on a lower surface of each of the upper wing, the left wing, and the right wing.

In some implementations of the flexible display device, the flexible display device further comprises upper, left and right foam pads respectively disposed between the upper wing, the left wing and the right wing of the flexible cover window and the upper, left and right side surfaces of the display module.

In some implementations of the flexible display device, the upper, left, and right foam pads are respectively attached to the upper, left, and right side surfaces of the display module and to the upper wing, the left wing and the right wing of the flexible cover window via an adhesive layer.

In some implementations of the flexible display device, the flexible display device further comprises: a chip-on film connected to the display panel of the display module; and a filling film filling a space defined between the chip-on film and the flexible cover window.

In some implementations of the flexible display device, the filling film is attached to the flexible cover window via an adhesive layer.

In some implementations of the flexible display device, the heat-dissipating plate has a plurality of through-holes defined therein, wherein each of the plurality of through-holes has a bent structure in the heat-dissipating plate, wherein a sidewall and a protrusion extending from the sidewall are formed in each of the plurality of through-holes.

In some implementations of the flexible display device, the flexible display device further comprises an adhesive layer disposed between the support plate and the heat-dissipating plate, wherein at least a portion of the protrusion formed in each of the plurality of through-holes is positioned in the adhesive layer.

A second aspect of the present disclosure provides a flexible cover window assembly comprising: a flexible cover window including a base film, and an anti-glare layer, an anti-reflection layer and an anti-fingerprint layer sequentially stacked on an upper surface of the base film; a light-blocking layer disposed along and on an edge of a lower surface of the base film of the flexible cover window; and an adhesive layer disposed on a lower surface of the flexible cover window.

In some implementations of the flexible cover window assembly, the flexible cover window includes a flat portion, an upper wing extending from an upper side of the flat portion, a left wing extending from a left side of the flat portion, and a right wing extending from a right side of the flat portion.

In some implementations of the flexible cover window assembly, the light-blocking layer is disposed not only on the edge of the lower surface of the flat portion of the flexible cover window but also on a lower surface of each of the upper wing, the left wing, and the right wing.

Although the embodiments of the present disclosure have been described in more detail with reference to the accompanying drawings, the present disclosure is not necessarily limited to these embodiments, and can be modified in a various manner within the scope of the technical spirit of the present disclosure. Accordingly, the embodiments as disclosed in the present disclosure are intended to describe rather than limit the technical idea of the present disclosure, and the scope of the technical idea of the present disclosure is not limited by these embodiments.

Therefore, it should be understood that the embodiments described above are not restrictive but illustrative in all respects. The scope of protection of the present disclosure should be interpreted according to the scope of claims, and all technical ideas within an equivalent scope thereto should be interpreted as being included in the scope of rights of the present disclosure.

What is claimed is:

1. A flexible display device comprising:
a flexible cover window including a base film, an anti-glare layer, an anti-reflection layer and an anti-fingerprint layer, wherein the anti-glare layer, the anti-reflection layer and the anti-fingerprint layer are sequentially stacked on an upper surface of the base film;
a light-blocking layer disposed on and along an edge of a lower surface of the base film of the flexible cover window;
a display module disposed under the flexible cover window;
a support plate disposed under the display module; and
a heat-dissipating plate disposed under the support plate.

2. The flexible display device of claim 1, wherein the flexible cover window includes:
a flat portion,
an upper wing extending from an upper side of the flat portion,
a left wing extending from a left side of the flat portion, and
a right wing extending from a right side of the flat portion.

3. The flexible display device of claim 2, wherein the upper wing, the left wing and the right wing of the flexible cover window respectively cover upper, left and right side surfaces of the display module.

4. The flexible display device of claim 2, wherein the light-blocking layer is disposed on the edge of the lower surface of the flat portion of the flexible cover window, and is disposed on a lower surface of each of the upper wing, the left wing, and the right wing of the flexible cover window.

5. The flexible display device of claim 2, wherein the flexible display device further comprises upper, left and right foam pads respectively disposed between the upper wing, the left wing and the right wing of the flexible cover window and the upper, left and right side surfaces of the display module.

6. The flexible display device of claim 5, wherein the upper, left, and right foam pads are respectively attached to the upper, left, and right side surfaces of the display module, and are respectively attached to the upper wing, the left wing and the right wing of the flexible cover window, via an adhesive layer.

7. The flexible display device of claim 1, wherein the flexible display device further comprises:
a chip-on film connected to a display panel of the display module; and
a filling film filling a space defined between the chip-on film and the flexible cover window.

8. The flexible display device of claim 7, wherein the filling film is attached to the flexible cover window via an adhesive layer.

9. The flexible display device of claim 1, wherein the heat-dissipating plate has a plurality of through-holes defined therein,
wherein each of the plurality of through-holes has a bent structure in the heat-dissipating plate, and
wherein a sidewall and a protrusion extending from the sidewall are formed in each of the plurality of through-holes.

10. The flexible display device of claim 9, wherein the flexible display device further comprises an adhesive layer disposed between the support plate and the heat-dissipating plate, and
wherein at least a portion of the protrusion formed in each of the plurality of through-holes is positioned in the adhesive layer.

11. A flexible cover window assembly comprising:
a flexible cover window including a base film, an anti-glare layer, an anti-reflection layer and an anti-fingerprint layer, wherein the anti-glare layer, the anti-reflection layer and the anti-fingerprint layer sequentially stacked on an upper surface of the base film;
a light-blocking layer disposed along and on an edge of a lower surface of the base film of the flexible cover window; and
an adhesive layer disposed on a lower surface of the flexible cover window.

12. The flexible cover window assembly of claim 11, wherein the flexible cover window includes a flat portion, an upper wing extending from an upper side of the flat portion, a left wing extending from a left side of the flat portion, and a right wing extending from a right side of the flat portion.

13. The flexible cover window assembly of claim 12, wherein the light-blocking layer is disposed on the edge of the lower surface of the flat portion of the flexible cover window and is disposed on a lower surface of each of the upper wing, the left wing, and the right wing of the flexible cover window.
